(19) United States
(12) Patent Application Publication
(10) Pub. No.: US 2026/0305393 A1
(43) Pub. Date: Oct. 1, 2026

(54) PACKAGE STRUCTURE AND MANUFACTURING METHOD THEREOF

(71) Applicant: Taiwan Semiconductor Manufacturing Company, Ltd., Hsinchu (TW)

(72) Inventors: Tzuan-Horng Liu, Taoyuan City (TW); An-Jhih Su, Taoyuan City (TW)

(73) Assignee: Taiwan Semiconductor Manufacturing Company, Ltd., Hsinchu (TW)

(21) Appl. No.: 19/094,982

(22) Filed: Mar. 30, 2025

(51) Int. Cl. H10W 70/60; H10W 70/695; H10W 90/00; H10W 20/20; H10W 74/10

(52) U.S. Cl. CPC H10W 70/611; H10W 70/695; H10W 90/00; H10W 90/401; H10W 20/20; H10W 74/111; H10W 90/722; H10W 90/794

(57) ABSTRACT

A package structure including a first electronic component, a second electronic component, a first insulating layer, a second insulating layer, and an electrical connector is provided. The first insulating layer and the second insulating layer are stacked and disposed between the first electronic component and the second electronic component. The electrical connector penetrates through the first insulating layer and the second insulating layer to electrically connect the first electronic component and the second electronic component. A material of the first insulating layer is different from a material of the second insulating layer.

### BACKGROUND

The semiconductor industry has experienced rapid growth due to continuous improvements in the integration density of a variety of integrated circuit components (e.g., transistors, diodes, resistors, capacitors, etc.). In the packaging of integrated circuit components, semiconductor dies are stacked and bonded to other package components such as interposers and package substrates. As the demand for miniaturization, the increased density and corresponding decrease in area occupied by the integrated circuit components has surpassed the ability to bond the semiconductor die onto the package component. Although existing package component have allowed for a three-dimensional (3D) package that includes multiple semiconductor packages, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 1F illustrate portions of cross-section views of a manufacturing method of a package structure of an embodiment of the disclosure.

FIG. 2 illustrates a portion of top view of a package structure of an embodiment of the disclosure.

FIG. 3 illustrates a portion of cross-section view of a package structure of an embodiment of the disclosure.

FIGS. 4A to 4B illustrate portions of cross-section views of a manufacturing method of a package structure of an embodiment of the disclosure.

FIG. 4C illustrates a portion of top view of a package structure of an embodiment of the disclosure.

FIG. 4D illustrates a portion of cross-section view of a manufacturing method of a package structure of an embodiment of the disclosure.

FIG. 4E illustrates a portion of cross-section view of a manufacturing method of a package structure of an embodiment of the disclosure.

FIG. 5A to 5B illustrates illustrate portions of cross-section views of a manufacturing method of a package structure of an embodiment of the disclosure.

FIGS. 6A to 6C illustrate portion of cross-section views of a manufacturing method of a package structure of an embodiment of the disclosure.

FIG. 7 illustrates a portion of cross-section view of a manufacturing method of a package structure of an embodiment of the disclosure.

FIGS. 8A to 8D illustrate portions of cross-section views of a manufacturing method of a package structure of an embodiment of the disclosure.

FIG. 9 illustrate a portion of top view of a manufacturing method of a package structure of an embodiment of the disclosure.

FIG. 10 illustrates a portion of flow for a manufacturing method of a package structure of an embodiment of the disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the component in use or operation in addition to the orientation depicted in the figures. The apparatus may be otherwise oriented (rotated 90 degrees or at other orientations) and the spatially relative descriptors used herein may likewise be interpreted accordingly.

It will be understood that, although the terms “first”, “second”, “third” and the like, may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

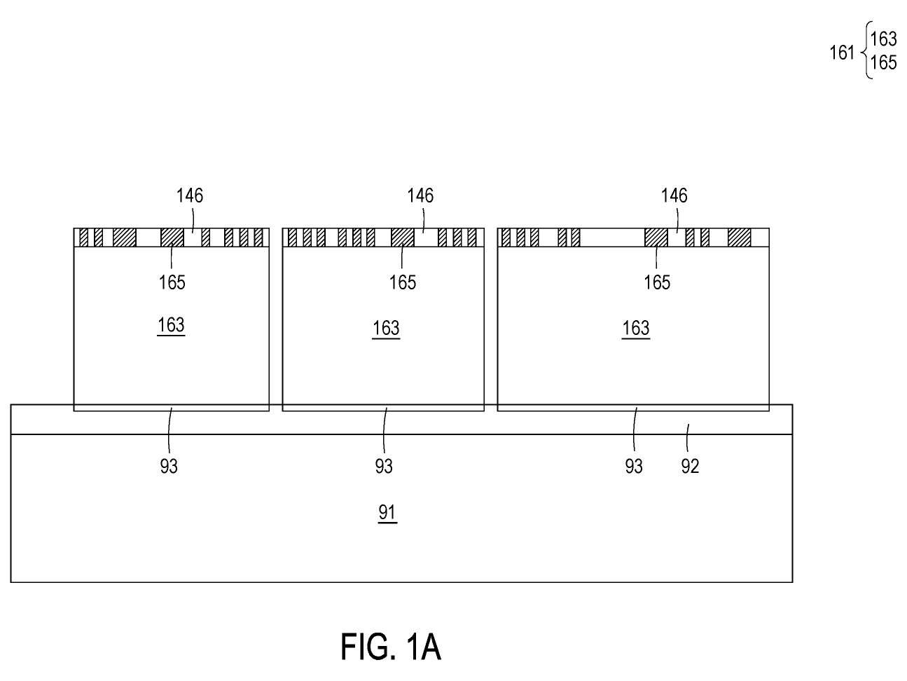

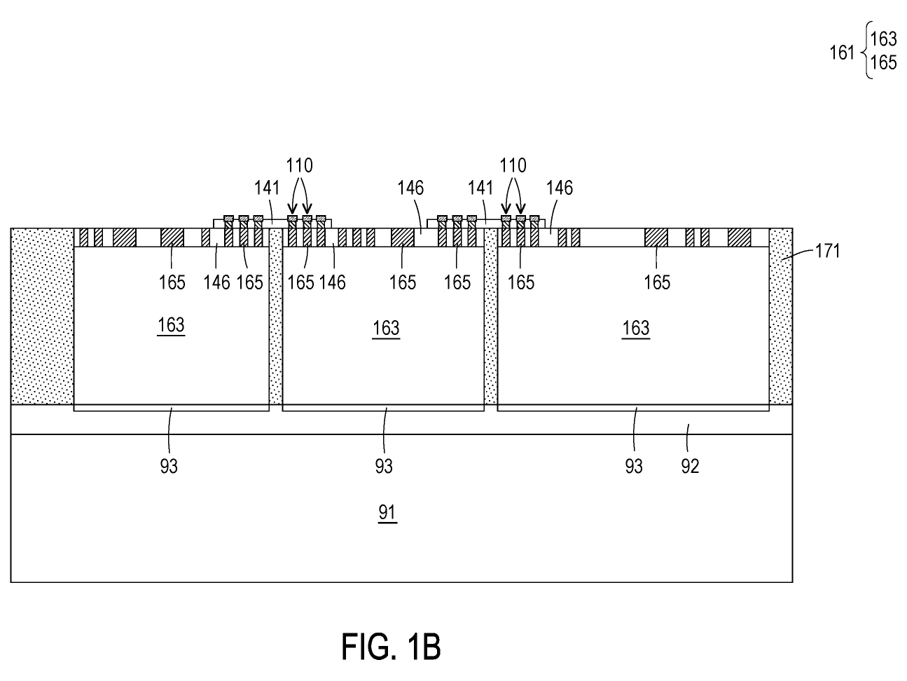

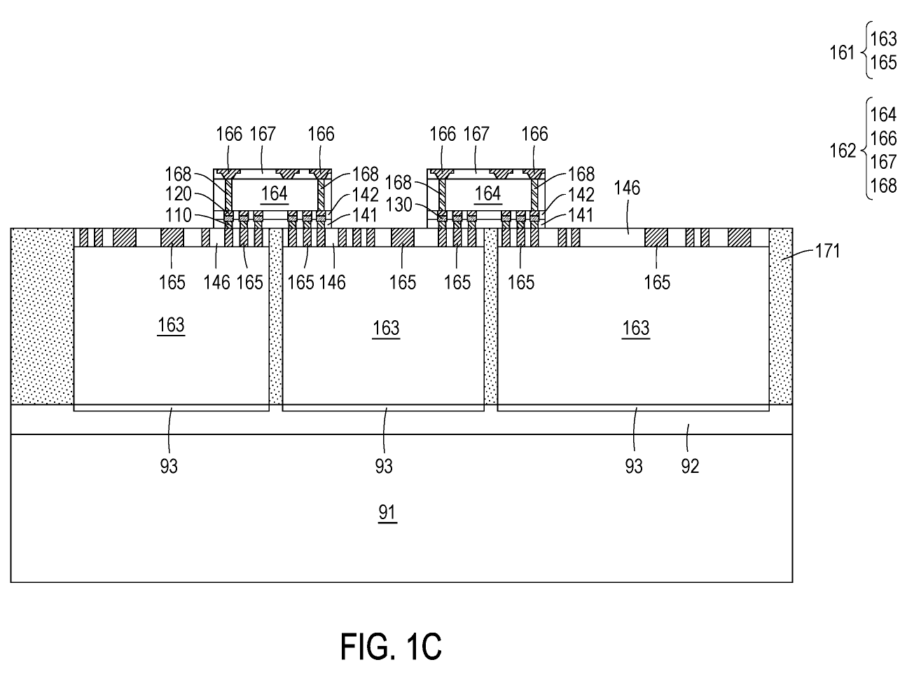

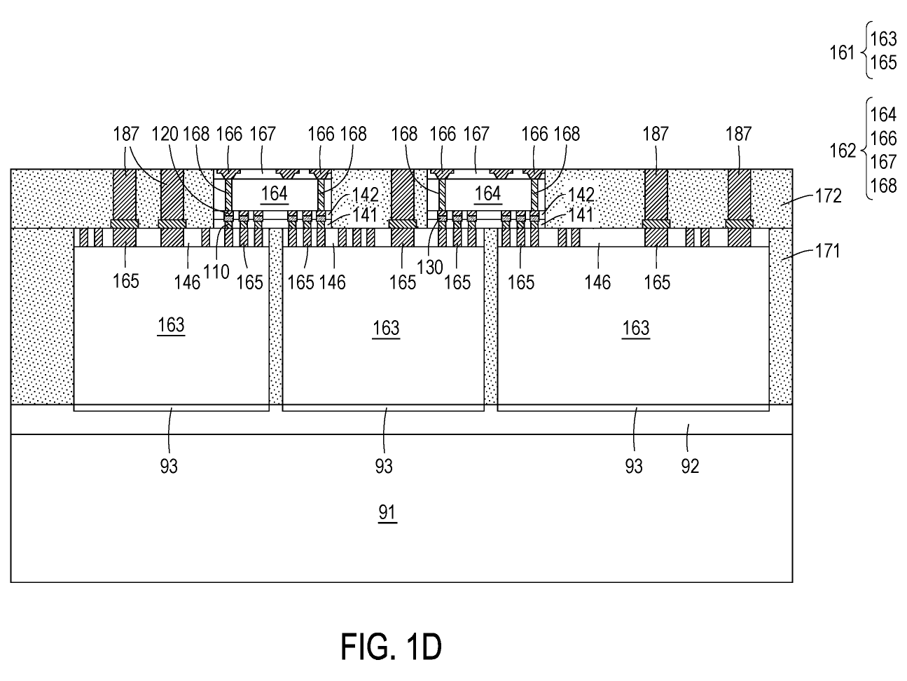

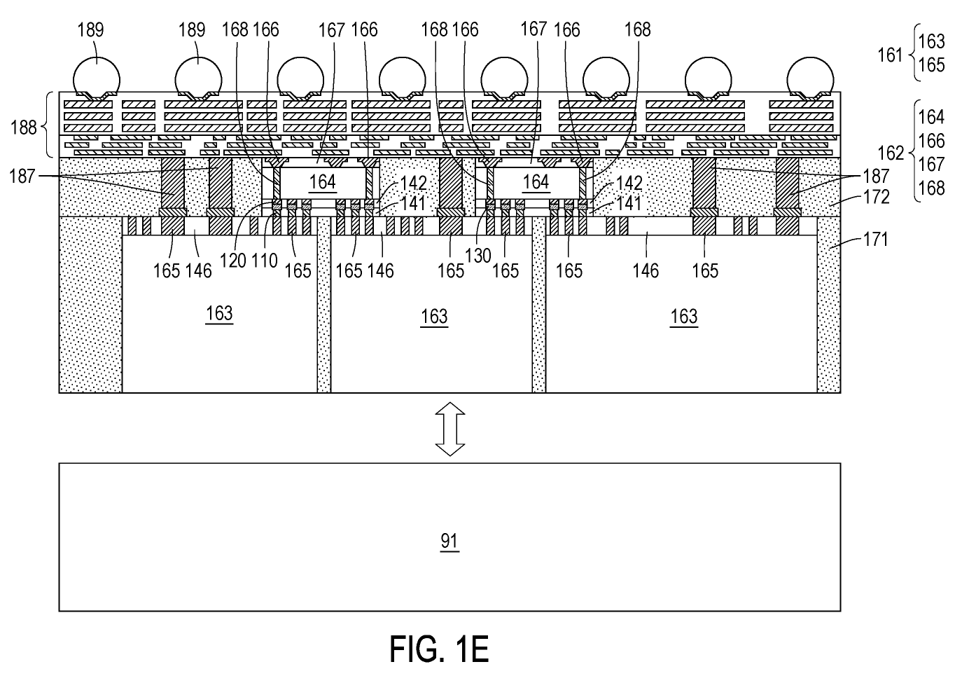

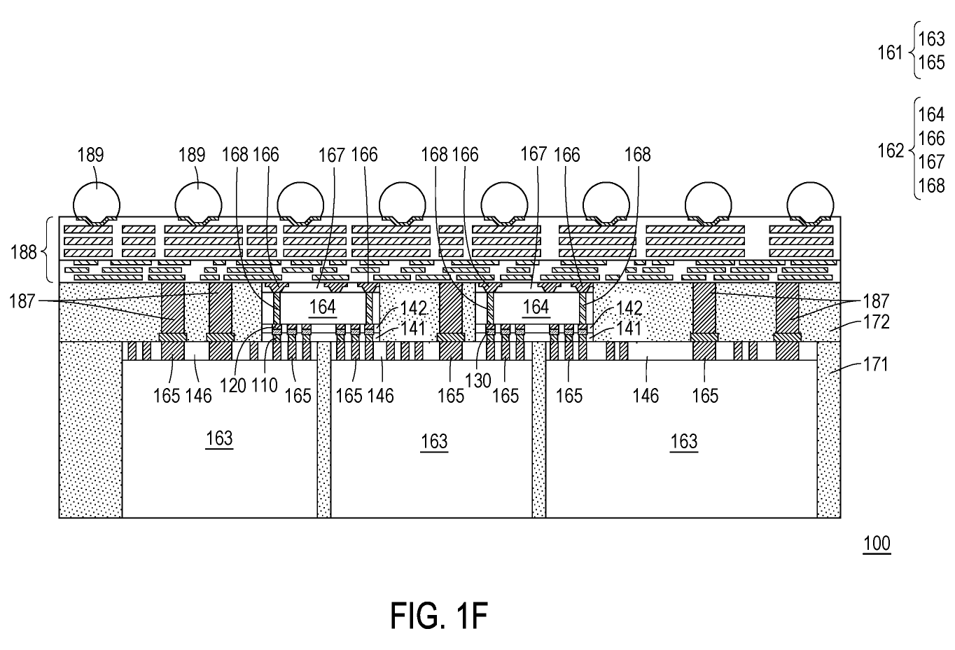

FIGS. 1A to 1F illustrate a portion of cross-section views of a manufacturing method of a package structure of an embodiment of the disclosure.

Referring to FIG. 1A, a carrier 91 is provided. The carrier 91 may be made of glass, wafer (e.g., a Si wafer), metal, polymer, or other suitable materials. A material of the carrier 91 is not limited in the disclosure, as long as the carrier 91 could carry components (e.g., one or more electronic components) or structures (e.g., one or more circuit structures) disposed or formed thereon in a subsequent manufacturing process. In an embodiment, a release layer 92 is disposed on the carrier 91. The release layer 92 may include a light to heat conversion (LTHC) adhesive layer, but the disclosure is not limited thereto.

Referring to FIG. 1A, one or more first electronic components 161 are provided. For example, the first electronic components 161 may be configured on the carrier 91. It is worth noting that only three first electronic components 161 are exemplarily illustrated in FIG. 1A, but the disclosure does not limit a number, a type, and/or an arrangement of the provided first electronic components 161. If there are a plurality of first electronic components 161, two of the first electronic components 161 may be homogeneous electronic components or may be heterogeneous electronic components. For example, one of the first electronic components 161 may be an application-specific integrated circuit (ASIC) chip, a dynamic random access memory (DRAM) chip, a static random access memory (SRAM), a system on chip (SoC), a high performance computing (HPC) chip, input/output (I/O) chip, high bandwidth memory (HBM) chip, a combination or a stack thereof, but the disclosure is not limited thereto.

In a possible embodiment (as described below, but not limited thereto), the first electronic components 161 may be provided with other components 93. When a corresponding first electronic component 161 is provided, a component 93 may already be disposed thereon. The component 93 may be in direct contact with the first electronic component 161, for example, there may be a corresponding adhesive layer (e.g., a die attached film (DAF)) disposed on a back side of the first electronic component 161.

In an embodiment, the first electronic component 161 includes a substrate 163 and one or more chip connectors 165. The substrate 163 may be a semiconductor substrate (e.g., a silicon substrate, but not limited). A side of the substrate 163 has a device area (not shown, could be formed by a front end of line (FEOL) process), and a surface on which the device area is disposed may be referred an active surface. In a design of a chip, a device (e.g., a transistor, but not limited) in the device area (e.g., the device in the device area of the first electronic component 161) may be electrically connected to the corresponding chip connector 165 through a corresponding circuit (e.g., a back end of line interconnect (BEOL interconnect) forming by a BEOL process). In addition, for clarity, not all chip connectors 165 are illustrated or labelled one by one in FIG. 1A or other similar figures.

In an embodiment, the chip connector 165 includes a conductive pillar or a conductive bump, for example, a copper-included (Cu-included) pillar, a Cu-included bump. In an embodiment, the chip connector 165 is embedded in an insulating layer 146 disposed on the substrate 163. The chip connector 165 embedded in the insulating layer 146 may be referred as a conductive via, for example, a Cu-included via. The chip connector 165 may be formed by a lithography process, a sputtering process, an electroplating process, and/or a removal process, but the disclosure is not limited thereto. In an embodiment, the chip connector 165 is referred as a portion of the BEOL structure. It is worth noting that the cross-sectional shape of the chip connectors 165 is illustrated for example in FIG. 1A or other similar figures, the cross-section of the chip connectors 165 may be the same or similar to a rectangle, a trapezoid, an inverted trapezoid, a combination thereabove, or other possible shapes.

Referring to FIG. 1B, a first encapsulant 171 is formed. The first encapsulant 171 is formed on the carrier 91 to encapsulate the first electronic components 161. A material for forming the first encapsulant 171 may include molding compound, molding underfill, epoxy resin, phenolic resins, silicon-containing resins, or the like. In an embodiment, a material of the first encapsulant 171 further includes filler or thermally conductive particles (not shown). The first encapsulant 171 may be applied by compression molding, transfer molding, or the like. In an embodiment, the first encapsulant 171 is referred to as a molding layer. In an embodiment, the first electronic components 161 are over-molded by a molding material for forming the first encapsulant 171; then, the excess molding material (a portion of the molding material above the first electronic components 161) is removed to accessibly reveal the first electronic components 161. For example, a planarizing process (e.g., grinding, chemical mechanical polishing (CMP), etching, combination thereof, etc.) is performed on the molding material until at least a portion of the top surfaces of the chip connectors 165 are accessibly revealed.

After performing the planarization process, the top surface of the insulating layer 146, the top surface of the first encapsulant 171, and/or the top surfaces of the chip connectors 165 become substantially leveled and flush with one another. In an embodiment, a portion of the first encapsulant 171 laterally covers the insulating layer 146. The first encapsulant 171 may extend along the sidewalls of the first electronic components 161. In an embodiment, the first encapsulant 171 fills the space between two of the first electronic components 161.

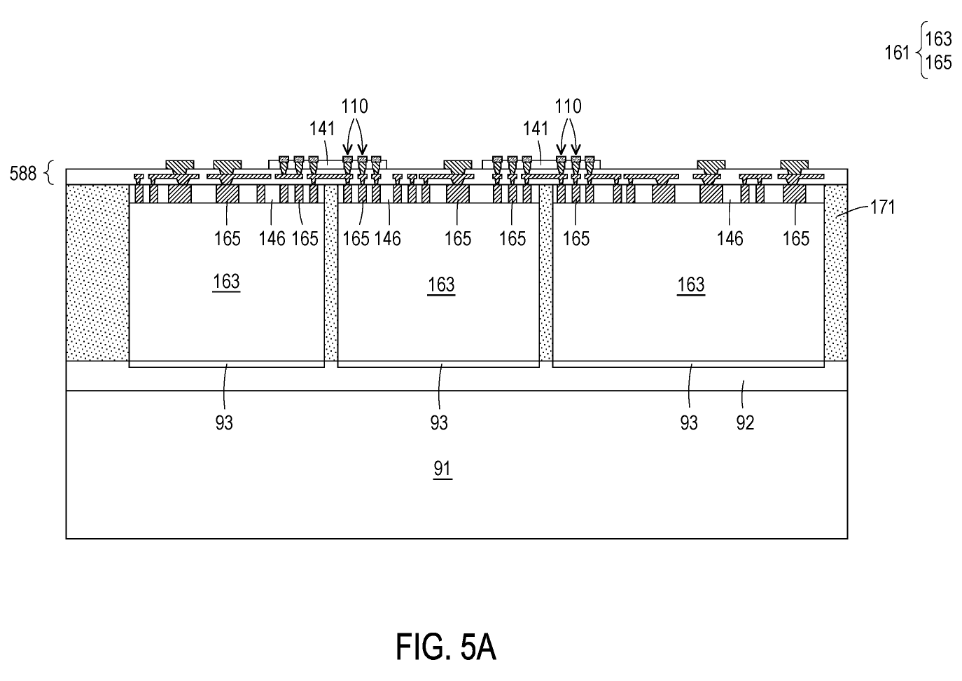

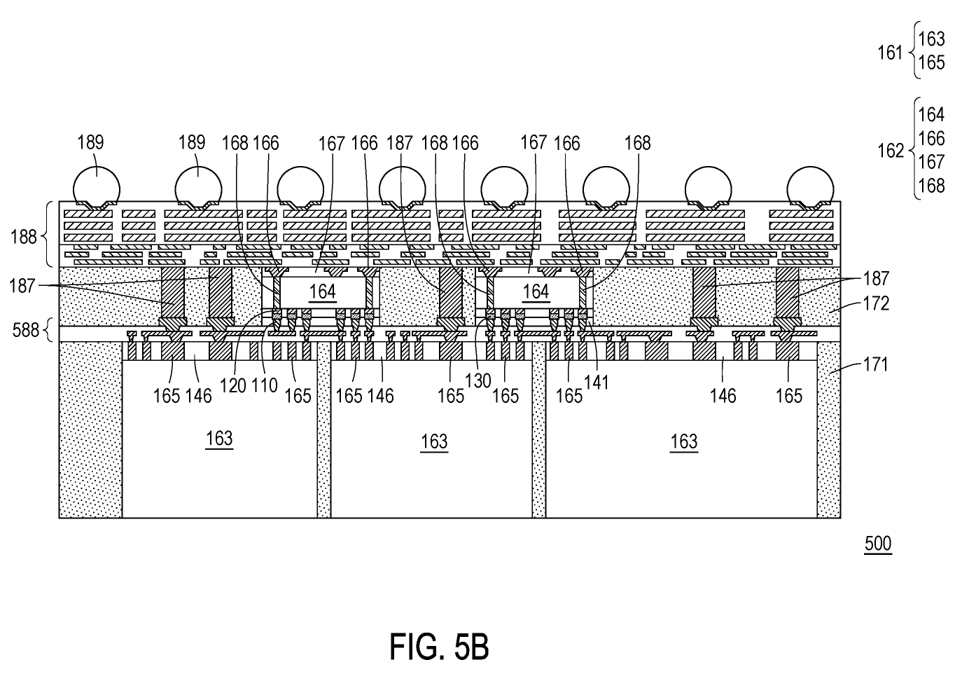

In an embodiment, a circuit structure (e.g., the circuit structure 588 as shown in FIG. 5) is formed after performing the planarization process, but the disclosure is not limited thereto.

Referring to FIG. 1B continuously, one or more first electrical connectors 110 could be formed. In an embodiment, the first electrical connector 110 includes a conductive pillar or a conductive bump, for example, a copper-included (Cu-included) pillar, a Cu-included bump. In an embodiment, a portion of the first electrical connector 110 is embedded in an insulating layer 141, but the disclosure is not limited thereto. The first electrical connector 110 may be formed by a lithography process, a sputtering process, an electroplating process, and/or a removal process, but the disclosure is not limited thereto. In addition, for clarity, not all first electrical connectors 110 are illustrated or labelled one by one in FIG. 1B or other similar figures.

In an embodiment, an insulating material is formed on the active surface of the first electronic component 161. Then, a lithography process is performed to form the insulating layer 141 having one or more openings to expose a corresponding circuit (e.g., the chip connector 165, but not limited) of the first electronic component 161. Then, a sputtering process, an electroplating process, and/or an appropriate process is/are performed to fill corresponding conductive material (e.g., nickel (Ni), copper (Cu), or tin (Sn)) in the opening. By adjusting one or more process conditions (e.g., time, reagent concentration, and/or current density, but not limited), the conductive material could have a corresponding thickness. Then, a removal process (e.g., a polishing process) is performed to form one or more connector (e.g., a portion of the first electrical connectors 110) embedded in the insulating layer 141. By adjusting one or more process conditions (e.g., a further forming process is performed; and/or, type or selectivity of an etching agent or a polishing slurry, but not limited), the first electrical connector 110 could be formed to protrude from, recessed in, either or substantially flush with the insulation layer.

In an embodiment, a patterned conductive layer is formed by a sputtering process (e.g., for forming a conductive seed layer, for example, a Cu layer), a lithography process (e.g., for forming a mask with a pattern for subsequent electroplating), an electroplating or other suitable processes (e.g., for forming one or more conductive layer, for example, a Ni-included layer, a Cu-included layer, and/or a Sn-included layer, but not limited), and a removal process (e.g., for removing the mask and the exposed conductive seed layer). As such, a conductor for being the first electrical connector 110 may be formed. Then, an insulating material at least laterally covering and/or enclosing the aforementioned conductor is formed. In an embodiment, the aforementioned insulating material may be formed to have a higher height than the aforementioned conductor, to cover a top surface of the aforementioned conductor; then, a removal process (e.g., an etching-back process) is performed to remove a portion of the insulating material to expose the aforementioned conductor. A portion of the aforementioned conductor may be removed during the aforementioned removal process. As such, one or more connector (e.g., a portion of the first electrical connectors 110) embedded in the insulating layer 141 is formed. A further forming process could be performed optionally, for example, a Sn-included layer could be formed on the aforementioned connector embedded in the insulating layer 141. By adjusting one or more process conditions (e.g., a further forming process is performed; and/or, type or selectivity of an etching agent or a polishing slurry, but not limited), the first electrical connector 110 could be formed to protrude from, recessed in, either or substantially flush with the insulation layer.

In an embodiment, the insulating layer 141 (corresponding to the aforementioned material) is a single film layer; or a stacked insulating layer of a plurality of insulating layers. In an embodiment, a material of the insulating layer 141 is polymer, for example, including polyimide (PI), polybenzoxazole (PBO), benzocyclobutene (BCB), a combination (e.g., co-polymer), a mixture, a modification or a stack thereof. The insulating layer 141 may be formed by coating, lamination, deposition or other appropriate methods.

In an embodiment, a topmost position (e.g., a top surface) of the insulating layer 141 and a topmost position (e.g., a top surface) of the first electrical connector 110 are substantially not leveled. For example, the topmost position of the insulating layer 141 may have a lower level than the topmost position of the first electrical connector 110. For example, the topmost position of an insulating layer (e.g., the insulating layer 142 will be described later) has a higher level than the topmost position of an electrical connector (e.g., the electrical connector 120 will be described later).

In an embodiment, the insulating layer 141 with a plurality of first electrical connectors 110 embedded therein is partially overlapped with one of the first electronic components 161 and another one of first electronic components 161.

Referring to FIG. 1C, one or more second electronic components 162 are provided. It is worth noting that only two second electronic components 162 are exemplarily illustrated in FIG. 1C, but the disclosure does not limit a number, a type, and/or an arrangement of the provided second electronic components 162. If there are a plurality of second electronic components 162, two of the second electronic components 162 may be homogeneous electronic components or may be heterogeneous electronic components. One of the second electronic components 162 and one of the first electronic components 161 may be homogeneous electronic components or may be heterogeneous electronic components. For example, one of the second electronic components 162 may be a large scale integration (LSI) chip, a very large scale integration (VLSI) chip, a through silicon via (TSV) chip, a bridge chip, a combination (e.g., a LSI chip having TSV) or a stack thereof, but the disclosure is not limited thereto.

In an embodiment, the second electronic component 162 includes a substrate 164. One or more second electrical connectors 120 could be formed and/or disposed on (below in FIG. 1C or other similar figures) the second electronic component 162. The second electrical connector 120 may be referred as a front side connector, but the disclosure is not limited thereto. The substrate 164 may be a semiconductor substrate (e.g., a silicon substrate, but not limited). The second electrical connector 120 is disposed on (below in FIG. 1C or other similar figures) a side of the substrate 164. In a design of a chip, a device (e.g., a transistor, but not limited) in a device area (e.g., the device in the device area of the second electronic component 162) may be electrically connected to the corresponding second electrical connector 120 through a corresponding circuit (e.g., a back end of line interconnect (BEOL interconnect); a through silicon via; and/or, a back side circuit structure). In addition, for clarity, not all second electrical connectors 120 are illustrated or labelled one by one in FIG. 1C or other similar figures. In an embodiment, the side where the second electrical connector 120 disposed on corresponds to the device area, but the disclosure is not limited thereto.

In an embodiment, the second electrical connector 120 includes a conductive pillar or a conductive bump, for example, a Cu-included pillar, a Cu-included bump. In an embodiment, the second electrical connector 120 is embedded in an insulating layer 142. The second electrical connector 120 embedded in the insulating layer 142 may be referred as a conductive via, for example, a Cu-included via, but the disclosure is not limited thereto.

In an embodiment, the second electrical connectors 120 may be formed by a lithography process, a sputtering process, an electroplating process, and/or a removal process, but the disclosure is not limited thereto. In an embodiment, a material and/or a formation process of the second electrical connector 120 may be the same or similar to the material and/or the formation process of the first electrical connector 110, but the disclosure is not limited thereto.

In an embodiment, the insulating layer 142 (corresponding to the aforementioned material) is a single film layer; or a stacked insulating layer of a plurality of insulating layers. In an embodiment, a material of the insulating layer 142 is polymer, for example, including polyimide (PI), polybenzoxazole (PBO), benzocyclobutene (BCB), a combination (e.g., co-polymer), a mixture, a modification or a stack thereof. The insulating layer 142 may be formed by coating, lamination, deposition or other appropriate methods. In an embodiment, the insulating layer 141 and the insulating layer 142 are substantially made of the different material, for example, a material similar to the material of the insulating layer 142, but has a different composition ratio, additions, and/or modification (e.g., modification with different functional group).

In a possible embodiment, the insulating layer 142 and the second electrical connectors 120 embedded therein may be provided with a corresponding second electronic component 162. That is, when a corresponding second electronic component 162 is provided, the insulating layer 142 and the second electrical connectors 120 embedded therein may already be disposed thereon. For example, the insulating layer 142 and the second electrical connectors 120 embedded therein is form on a wafer having a plurality of device areas for forming a plurality of second electronic component 162; then, an appropriate process (e.g., a dicing process) could be performed to form the second electronic components 162 having the insulating layer 142 and the second electrical connectors 120 already disposed on the second electronic components 162.

In the embodiment, one or more third electrical connectors 166 could be formed and/or disposed on the substrate 164. The third electrical connector 166 may be referred as a chip connector, for example, a back side connector, but the disclosure is not limited thereto. The third electrical connector 166 is disposed on another side of the substrate 166, and opposite to the side where the second electrical connector 120 disposed thereon. A device (e.g., a transistor, but not limited) may be electrically connected to the corresponding third electrical connector 166 through a corresponding circuit (e.g., a back end of line interconnect (BEOL interconnect); a through silicon via (TSV); and/or, a back side circuit structure). For example, at least one of the second electrical connector 120 and at least one of the third electrical connector 166 disposed on opposite sides of the substrate 164 is electrically connected by a through silicon via 168 penetrating through the substrate 164. In addition, for clarity, not all third electrical connectors 166 are illustrated or labelled one by one in FIG. 1C or other similar figures.

In an embodiment, the third electrical connector 166 includes a conductive pillar, a conductive bump, a conductive via, a circuit, a combination or a stack thereof, but the disclosure is not limited thereto. In an embodiment, the third electrical connector 166 is embedded in an insulating layer 167.

In an embodiment, the third electrical connector 166 may be formed by a lithography process, a sputtering process, an electroplating process, and/or a removal process, but the disclosure is not limited thereto. In an embodiment, a material and/or a formation process of the third electrical connector 166 may be the same or similar to the material and/or the formation process of the first electrical connector 110 and/or the second electrical connector 120, but the disclosure is not limited thereto.

In an embodiment, the insulating layer 167 (corresponding to the aforementioned material) is a single film layer; or a stacked insulating layer of a plurality of insulating layers. In an embodiment, a material of the insulating layer 167 is polymer, for example, including polyimide (PI), polybenzoxazole (PBO), benzocyclobutene (BCB), a combination (e.g., co-polymer), a mixture, a modification or a stack thereof. The insulating layer 167 may be formed by coating, lamination, deposition or other appropriate methods.

In an embodiment, the insulating layer 167 and/or third electrical connector 166 is/are considered as a portion of the second electronic component 162. That is, the second electronic component 162 includes the substrate 164, and could further include the insulating layer 167 and/or third electrical connector 166. It is worth noting that the cross-sectional shape of the third electrical connector 166 is illustrated for example in FIG. 1C or other similar figures. The third electrical connector 166 may be an on-chip fan-in redistribution layer, a portion of an on-chip fan-in redistribution layer, or a conductive terminal on an on-chip fan-in redistribution layer.

Referring to FIG. 1C continuously, the second electronic component 162 could be bonded with one or more first electronic components 161.

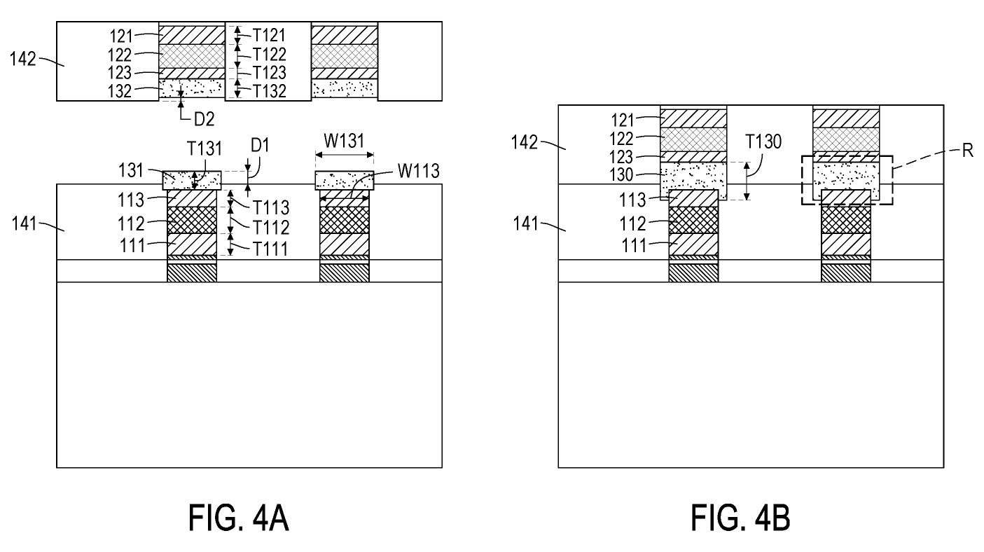

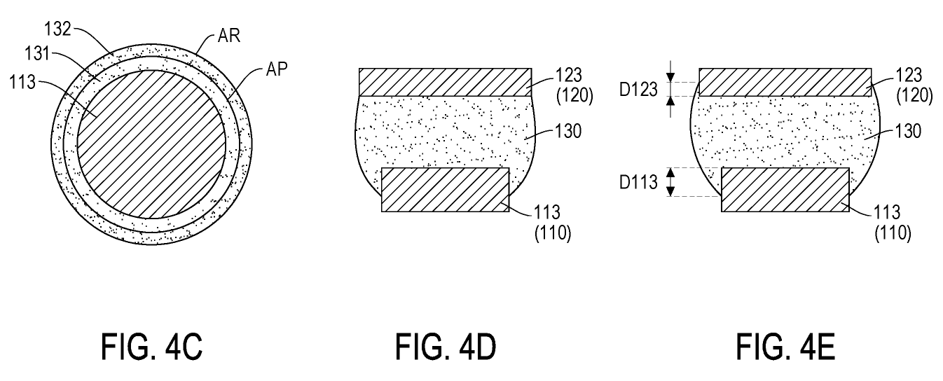

A detail of the bonding process is schematically illustrated in FIGS. 4A and 4B.

In an embodiment, as shown in FIG. 4A (note: the second electronic component 162 as shown in FIG. 4A is flipped upside-down), a topmost position (e.g., a top surface) of the insulating layer 141 has a higher level than a topmost position (e.g., a top surface) of the first electrical connector 110; and, a topmost position (e.g., a top surface) of the insulating layer 142 may have a lower level than a topmost position (e.g., a top surface) of the second electrical connector 120. That is, the first electrical connector 110 is protrude from the insulation layer 141; and, the second electrical connector 120 is recessed in the insulation layer 142.

As shown in FIG. 4A, the first electrical connector 110 may further include a first conductive bonding layer 131; and/or, the second electrical connector 120 may further include a second conductive bonding layer 132. The first conductive bonding layer 131 forms a protrusion protruding from the insulating layer 141. In an embodiment, a distance (e.g., the height D1 of the protrusion) between the end of the protrusion (e.g., the topmost position of the first electrical connector 110) and the insulating layer 141 is about 1 µm ~ 2.5 µm.

Comparing with other portions of the first electrical connector 110 and second electrical connector 120, the first conductive bonding layer 131 and/or the second conductive bonding layer 132 have a lower melting point. For example, the first electrical connector 110 includes a stack of a first conductive layer 111, a second conductive layer 112, a third conductive layer 113, and the first conductive bonding layer 131; and, the second electrical connector 120 includes a stack of a fourth conductive layer 121, a fifth conductive layer 122, a sixth conductive layer 123, and the second conductive bonding layer 132. The first conductive layer 111, the second conductive layer 112, the third conductive layer 113, the fourth conductive layer 121, the fifth conductive layer 122, the sixth conductive layer 123 include a Cu-based (atomic concentration of Cu is greater than or substantially equal to 80%) layer or a Ni -based (atomic concentration of Ni is greater than or substantially equal to 80%) layer. The first conductive bonding layer 131 and/or the second conductive bonding layer 132 include a Sn-based (atomic concentration of Sn is greater than or substantially equal to 80%) layer. For example, the first conductive layer 111 is a Cu-based layer having a thickness T111 about 3µm ~ 5µm; the second conductive layer 112 is a Ni-based layer having a thickness T112 about 4µm ~ 6µm; the third conductive layer 113 is a Cu-based layer having a thickness T113 about 0.5µm ~ 2.0 µm; and, first conductive bonding layer 131 is a Sn-based layer having a thickness T131 about 0.5 µm ~ 4.0 µm; the fourth conductive layer 121 is a Cu-based layer having a thickness T121 about 3.0 µm ~ 5.0 µm; the fifth conductive layer 122 is a Ni-based layer having a thickness T122 about 4.0 µm ~ 6.0 µm; the sixth conductive layer 123 is a Cu-based layer having a thickness T123 about 0.5µm ~ 2.0 µm; and, the second conductive bonding layer 132 is a Sn-based layer having a thickness T132 about 0.5 µm ~ 4.0 µm.

In an embodiment, the first conductive layer 111, the second conductive layer 112 and the third conductive layer 113 have similar material, and there may be no obvious interface therebetween. For example, the first conductive layer 111, the second conductive layer 112 and the third conductive layer 113 are Cu-based layers, and could be regarded as a Cu-based pillar.

For a subsequent bonding process, the protrusion of the first electrical connector 110 could be configured to correspond or align with the recess of the insulating layer 142 corresponding to the second electrical connector 120.

In an embodiment, an accommodation volume of the recess could be smaller than or substantially equal to a protruding volume of the protrusion. For example, as shown in FIGS. 4A and 4C, a product of the projected area AR multiplied by the depth D2 of the recess is about 70%~100% of a product of the projected area AP multiplied by the height D1 of the protrusion. As such, a formation of void may be reduced, and the quality of bonding process may be improved.

In an embodiment, the projected area AR of the recess may be greater than or substantially equal to the projected area AP of the protrusion. For example, as shown in FIG. 4C, the projected area AR of the recess is about 100%~110% of the projected area AP of the protrusion. As such, a corresponding step (e.g., an alignment step) for the subsequent bonding process may be easier.

As shown in FIGS. 4A to 4B, the insulating layer 142 disposed on the second electronic component 162 is bonded with the insulating layer 141 disposed on the first electronic component 161; and, the second electrical connector 120 disposed on the second electronic component 162 is bonded with the first electrical connector 110 disposed on the first electronic component 161.

Preliminarily, the second electronic component 162 and the first electronic component 161 could be configured such that the second electrical connector 120 and the first electrical connector 110 thereof face and align to each other.

Then, the protrusions protruding from the insulating layer 141 is inserted into the recesses recessed from the insulating layer 142; further, the first conductive bonding layer 131 and the second conductive bonding layer 132 are in contact with each other.

Before and/or during the first conductive bonding layer 131 and the second conductive bonding layer 132 being closer, and/or when the first conductive bonding layer 131 and the second conductive bonding layer 132 being in contact with, a thermal treatment is performed. Subsequently, the first electronic component 161 and the second electronic component 162 being closer continuously and/or the thermal treatment is performed continuously, so that the insulating layer 141 and the insulating layer 142 are bonded with each other, and/or the first conductive bonding layer 131 defining the protrusions are jointed with the second conductive bonding layer 132 exposed in the recesses. The thermal treatment and/or an additional treatment may be further performed, such that the first conductive bonding layer 131 and/or the second conductive bonding layer 132 may reflow, and the recesses may be substantially filled by the molten first conductive bonding layer 131 and/or the molten second conductive bonding layer 132, and a conductive bonded layer 130 (e.g., as shown in FIG. 4B) constituted from the first conductive bonding layer 131 (e.g., as shown in FIG. 4A) and the second conductive bonding layer 132 (e.g., as shown in FIG. 4A) is formed after completing the aforementioned bonding process. In an embodiment, the conductive bonded layer 130 is a Sn-based layer having a thickness T130 about 1.0 µm ~ 8.0 µm.

In an embodiment, a maximum temperature of the aforementioned thermal treatment is lower than melting point of the first conductive layer 111, the second conductive layer 112, the third conductive layer 113, the fourth conductive layer 121, the fifth conductive layer 122, and/or the sixth conductive layer 123. Therefore, compared with the structure (e.g., the structure as shown in FIG. 4A) before the conductive bonded layer 130 is formed and the structure (e.g., the structure as shown in FIG. 4B) after the conductive bonded layer 130 is formed, the morphology of the first conductive layer 111, the second conductive layer 112, the third conductive layer 113, the fourth conductive layer 121, the fifth conductive layer 122, and/or the sixth conductive layer 123 has/have no obvious change substantially. However, a corresponding eutectic (e.g., a Cu-Sn eutectic) may still be formed at the interface between two layers with different-based material. The bonding quality may be improved by a formation of metal eutectic bonding.

In an embodiment, as shown in FIG. 4A, a maximum horizontal dimension (e.g., the width W131) of the first conductive bonding layer 131 is wider than a maximum horizontal dimension of the conductive layer underlying thereto (e.g., the width W113 of the third conductive layer 113 underlying and in contact with the first conductive bonding layer 131). For example, the maximum horizontal dimension (e.g., the width W131) of the first conductive bonding layer 131 is about 103% ~ 110% of the maximum horizontal dimension (e.g., the width W113) of the third conductive layer 113. Additionally, compared to the insulating layer 142, the insulating layer 141 have lower hardness or lower glass transition point (Tg). Therefore, during the aforementioned bonding process, the formed conductive bonded layer 130 could cover the edge of the third conductive layer 113 through corresponding bonding pressure or material characteristics, as a result shown in FIGS. 4D and/or 4E for example. As such, the bonding quality could be improved. Additionally, the overflow of the molten first conductive bonding layer 131 and/or the molten second conductive bonding layer 132 in the horizontal direction could be reduced, thereby the possibility of short circuits in adjacent electrical connectors in the horizontal direction could be reduced.

Referring to FIG. 1D, a second encapsulant 172 is formed. The second encapsulant 172 is formed on the carrier 91 to encapsulate the second electronic components 162. In an embodiment, a material and/or a formation process of the second encapsulant 172 may be the same or similar to the material and/or the formation process of the first encapsulant 171, but the disclosure is not limited thereto. In an embodiment, the second electronic components 162 are over-molded by a molding material for forming the second encapsulant 172; then, the excess molding material (a portion of the molding material above the second electronic components 162) is removed to accessibly reveal the second electronic components 162. For example, a planarizing process (e.g., grinding, chemical mechanical polishing (CMP), etching, combination thereof, etc.) is performed on the molding material until at least a portion of the top surfaces of the third electrical connectors 166 are accessibly revealed.

In an embodiment, one or more conductors 187 penetrating through the second encapsulant 172 are formed to electrically connect to one or more corresponding first electronic components 161. For example, the conductor 187 is landed on a corresponding chip connector 165 of the first electronic component 161. The conductor 187 may be referred as a through molding via (TMV) or a through insulator via (TIV), but the disclosure is not limited thereto. In addition, for clarity, not all connectors 187 are illustrated or labelled one by one in FIG. 1D or other similar figures.

In an embodiment, after the aforementioned molding material is formed, a removal process (e.g., a drilling process, or an etching process, but not limited) is performed for forming a hole to exposed a conductor (e.g., a corresponding chip connector 165, a corresponding pad, or a corresponding circuit) below the formed molding material. Then, a corresponding conductive material could be filled in the opening for forming the conductor 187.

In an embodiment, the conductor 187 is a pre-formed conductor. For example, before the aforementioned molding material is formed, a pre-formed conductor is formed by an appropriate process to electrically connect to one or more corresponding first electronic components 161. Then, the aforementioned molding material for forming the second encapsulant 172 to encapsulate the second electronic components 162 and the pre-formed conductors. If the second electronic components 162 and/or the pre-formed conductors are over-molded by the molding material, and the excess molding material is removed to accessibly reveal the second electronic components 162 and the pre-formed conductors.

In an embodiment, a planarization process is performed. After performing the planarization process, the top surfaces of the third electrical connectors 166, the top surface of the insulating layer 167, the top surfaces of the conductors 187, and/or the top surface of the second encapsulant 172 become substantially leveled and flush with one another. In an embodiment, a portion of the second encapsulant 172 laterally covers the insulating layer 167. In an embodiment, a portion of the second encapsulant 172 laterally covers the third electrical connector 166. The second encapsulant 172 may extend along the sidewalls of the second electronic components 162. In an embodiment, the second encapsulant 172 fills the space between two of the second electronic components 162.

Referring to FIG. 1E, a circuit structure 188 electrically connected to the second electronic component 162 and/or the conductor 187 is formed by an appropriate process. The circuit structure 188 includes one or more insulating layers and one or more conductive layers. It should be noted that the disclosure does not limit the number of layers of the conductive layers and/or the insulating layers. A circuit consisting of a portion of the one or more conductive layers could be electrically connected to a corresponding second electronic component 162 and/or a corresponding conductor 187. In addition, for clarity, in FIG. 1E or other similar figures, the corresponding boxed regions including oblique lines in the circuit structure 188 may be the corresponding conductive layers thereof, and/or the corresponding blank boxed region in the circuit structure 188 may be the corresponding insulating layers thereof. In an embodiment, the topmost conductive layer for being in contact with a conductive terminal 189 may be referred to as an under-ball metallurgy (UBM) layer. In an embodiment, the circuit structure 188 is referred as a redistribution layer (RDL), for example, a fan-out redistribution layer (FORDL). In an embodiment, a thickness of the circuit structure 188 is about 30 µm (micrometer) ~ 200 µm; for example, 50 µm ~ 150 µm.

Referring to FIG. 1E continuously, one or more conductive terminals 189 are formed after forming the circuit structure 188. The conductive terminals 189 may be electrically connected a corresponding circuit of the circuit structure 188. Forms or shapes of the conductive terminals 189 may include a conductive pillar, a solder ball, a conductive bump, but the disclosure is not limited thereto. The conductive terminals 189 may be formed by a ball placement process, a reflow process, and/or other suitable processes. In addition, for clarity, not all conductive terminals 189 are illustrated or labelled one by one in FIG. 1E or other similar figures.

In an embodiment, a plurality of package structures (e.g., a package structure the same or similar to the package structure 100 as shown in FIG. 1F) may be formed through a singulation process. The singulation process may include, for example, a dicing process/cutting process to cut through the first encapsulant 171, the second encapsulant 172 and/or the circuit structure 188. It should be noted that similar element reference numerals are applied to the singulated elements after the singulation process. For example, the first electronic components 161 (as shown in FIG. 1E) may be the first electronic components 161 (as shown in FIG. 1F) after singulation, the first encapsulant 171 (as shown in FIG. 1E) may be the first encapsulant 171 (as shown in FIG. 1F) after singulation, the second electronic component 162 (as shown in FIG. 1E) may be the second electronic component 162 (as shown in FIG. 1F) after singulation, the second encapsulant 172 (as shown in FIG. 1E) may be the second encapsulant 172 (as shown in FIG. 1F) after singulation, and the circuit structure 188 (as shown in FIG. 1E) may be the circuit structure 188 (as shown in FIG. 1F) after singulation, and so on. Other singulated elements follows the same element reference numerals rules described above, and will not be repeated or particularly illustrated here.

Referring to FIG. 1E continuously, the carrier 91 and the structure disposed thereon are separated from each other. For example, light, heating, cooling, or other appropriate methods may be used to reduce a bonding force of the release layer 92 (if any) and/or the adhesive layer (e.g., a type of the component 93, if any) or to further remove the release layer 92 (if any) and/or the adhesive layer, to separate the carrier 91 and the structure thereon from each other by applying force.

It should be noted that the disclosure does not limit sequence of the formation of the conductive terminal 189, the singulation process (if any), the separation of the carrier 91 and the structure disposed thereon.

With reference to FIG. 1F, production of the package structure 100 of the embodiment may be roughly completed after the above steps.

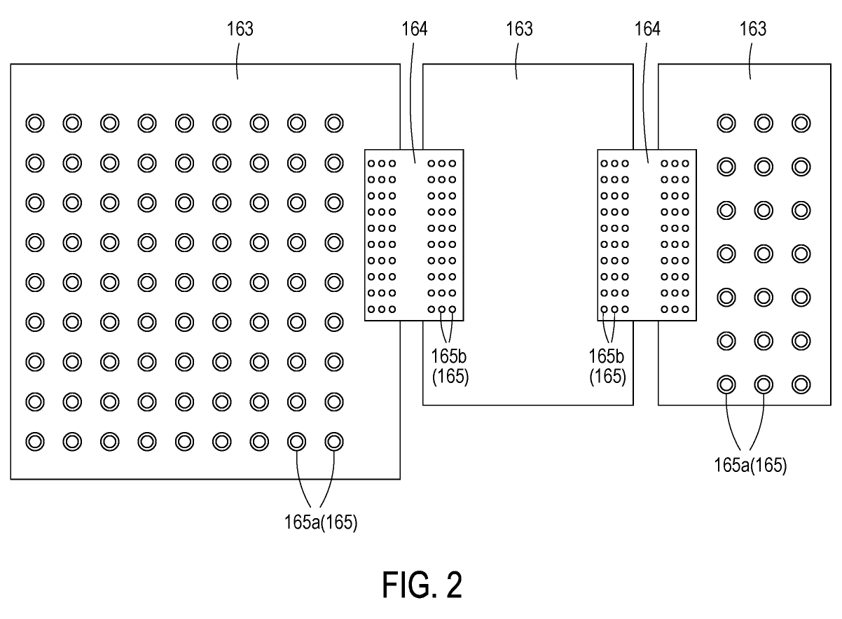

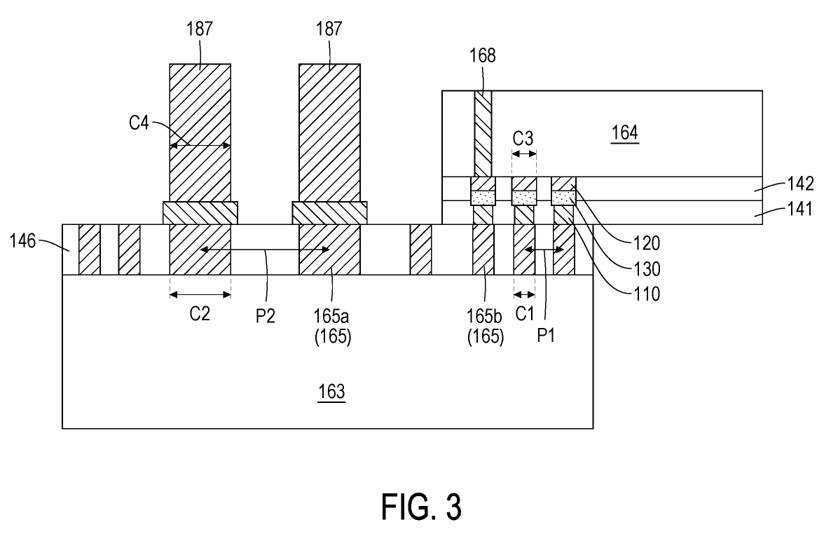

FIG. 1F is also a schematic cross-sectional view of the package structure according to an embodiment of the disclosure. FIG. 2 could be a portion of top view of a package structure corresponding to the package structure as shown in FIG. 1F. FIG. 3 could be a portion of cross-section view of a package structure corresponding to one of the first electronic components and one of the second electronic components of the package structure as shown in FIG. 1F. FIG. 4B could be a portion of cross-section view of a package structure corresponding to one of the electrical connectors and one of the second electrical connectors of the package structure as shown in FIG. 1F. FIGS. 4D and 4E could be a portion of cross-section views of a package structure corresponding to a conductive bonded layer and conductive layers disposed and bonded to opposite sides thereof, for example, corresponding to the region R as shown in FIG. 4B.

Referring to FIG. 1F, a package structure 100 includes at least one (e.g., one or more) first electronic component 161, at least one (e.g., one or more) second electronic component 162, a first insulating layer 141, a second insulating layer 142, and at least one electrical connector 110, 130 and 120. The first insulating layer 141, the second insulating layer 142, and the electrical connector 110, 130 and 120 are disposed between the first electronic component 161 and the second electronic component 162. The electrical connector 110, 130 and 120 penetrates through the first insulating layer 141 and the second insulating layer 142 to electrically connect the first electronic component 161 and the second electronic component 162.

Referring to FIGS. 1F, 3 and 4B, in an embodiment, a material of the first insulating layer 141 includes polymer, and a material of the second insulating layer 142 includes another polymer. That is, the first insulating layer 141 and the second insulating layer each include different polymers. In an embodiment, the polymer included in the first insulating layer 141 has a lower hardness or lower glass transition point (Tg) than the polymer included in the second insulating layer 142. In an embodiment, the polymer-based (weight percentage of polymer is greater than or substantially equal to 80 wt%) insulating layer 141 has a lower hardness or lower glass transition point (Tg) than the polymer-based insulating layer 142.

Referring to FIGS. 1F, 3, 4B, 4D and 4E, in an embodiment, the electrical connector 110, 130 and 120 includes a first electrical connector 110, a conductive bonded layer 130, and a second electrical connector 120. The conductive bonded layer 130 is sandwiched between the frst electrical connector 110 and the second electrical connector 120, and the conductive bonded layer 130 further covers a side wall of at least one of the first electrical connector 110 and the second electrical connector 120. In an embodiment, as shown in FIG. 4E, the conductive bonded layer 130 covers side walls of both of the first electrical connector 110 and the second electrical connector 120. It is worth noting that, the structure as shown in FIG. 4D and the as shown in FIG. 4E may correspond to different package structures; or, the structure as shown in FIG. 4D and the as shown in FIG. 4E may correspond to different electrical connectors 110, 130 and 120 of a same package structure; or, the structure as shown in FIG. 4D and the as shown in FIG. 4E may correspond to different cross-section views of a same electrical connector 110, 130 and 120. In an embodiment, as shown in FIG. 4E, if the conductive bonded layer 130 covers side walls of both of the first electrical connector 110 and the second electrical connector 120, a covering depth D113 of the conductive bonded layer 130 covering the side wall of the first electrical connector 110 is larger than a covering depth D123 of the conductive bonded layer 130 covering the side wall of the second electrical connector 120, along the stacking direction of the first electronic component 161 and the second electronic component 162.

Referring to FIGS. 1F, 3, 4B, 4D and 4E, in an embodiment, the polymer-based insulating layer 141 has a lower hardness or lower glass transition point (Tg) than the polymer-based insulating layer 142; a width C3 of the second electrical connector 120 is wider than a width C1 and the first electrical connector 110; and the conductive bonded layer 130 at least covers the side wall of the first electrical connector 110. In an embodiment, a width of the conductive bonded layer 130 is wider than the width C3 of the second electrical connector 120 and the width C1 and the first electrical connector 110.

In an embodiment, the package structure 100 further include a first encapsulant 171, and a second encapsulant 172. The first encapsulant 171 encapsulate the first electronic component 161. The second encapsulant 172 encapsulate the second electronic component 162. A thickness of the first encapsulant 171 is about 500 µm (micrometer) ~ 900 µm; for example, about 600 µm ~ 800 µm. A thickness of the second encapsulant 172 is about 30 µm ~ 150 µm; for example, about 50 µm ~ 100 µm.

In an embodiment, the package structure 100 further include one or more conductors 187 penetrating through the second encapsulant 172. A height of the conductor 187 is substantially the same or similar to the thickness of the second encapsulant 172. In an embodiment, a width C4 of the conductor 187 is about 20 µm ~ 280 µm; for example, 20 µm ~ 60 µm; or about 30 µm ~ 50 µm.

In an embodiment, the package structure 100 further include a third insulating layer 146 and a plurality of chip connectors 165. The third insulating layer 146 is disposed on the substrate 163 of the first electronic component 161. The chip connectors 165 penetrate through the third insulating layer 146. One of the conductors 187 could be landed on one of the chip connectors 165 (e.g., the chip connectors 165a). One of the first electrical connectors 110 could be landed on another one of the chip connectors 165 (e.g., the chip connectors 165b). In an embodiment, a width C2 of the chip connectors 165a is wider than a width C1 of the chip connectors 165b. In an embodiment, a width C2 of the chip connectors 165a is substantially the same or similar to the width C4 of the conductor 187. In an embodiment, a width C2 of the chip connectors 165a is about 20 µm ~ 60 µm; for example, about 30 µm ~ 50 µm. In an embodiment, a width C1 of the chip connectors 165b is substantially the same or similar to the width C1 of the first electrical connectors 110. In an embodiment, a width C1 of the chip connectors 165b is about 2 µm ~ 8 µm; for example, about 3 µm ~ 6 µm. In an embodiment, a pitch P2 between two adjacent chip connectors 165a is wider than a pitch P1 between two adjacent chip connectors 165b. In an embodiment, the pitch P2 between two adjacent chip connectors 165a is about 40 µm ~ 400 µm; for example, about 40 µm ~ 150 µm. In an embodiment, the pitch P1 between two adjacent chip connectors 165b is about 4 µm ~ 20 µm; for example, about 6 µm ~ 12 µm.

FIG. 5A to 5B illustrates illustrate a portion of cross-section views of a manufacturing method of a package structure of an embodiment of the disclosure.

In an embodiment, the structure and/or step as shown in FIG. 5A could be continued from the structure and/or step as shown in FIG. 1A.

Referring to FIG. 5A, a first encapsulant 171, which is the same or similar to the structure and/or step as shown in FIG. 1B, is formed. Then, a circuit structure 588 is formed by an appropriate process. The circuit structure 588 includes one or more insulating layers and one or more conductive layers. It should be noted that the disclosure does not limit the number of layers of the conductive layers and/or the insulating layers. A circuit consisting of a portion of the one or more conductive layers could be electrically connected to a corresponding chip connector 165. In addition, for clarity, in FIG. 5A or other similar figures, the corresponding boxed regions including oblique lines in the circuit structure 588 may be the corresponding conductive layers thereof, and/or the corresponding blank boxed region in the circuit structure 588 may be the corresponding insulating layers thereof. In an embodiment, the circuit structure 588 is referred as a redistribution layer (RDL), for example, a fan-out redistribution layer (FORDL). In an embodiment, a thickness of the circuit structure 588 is about 10 µm ~ 30 µm; for example, 15 µm ~ 200 µm.

Referring to FIG. 5A continuously, one or more first electrical connectors 110 embedded in the insulating layer 141 could be formed, which is the same or similar to the structure and/or step as shown in FIG. 1B.

As shown in FIGS. 5A to 5B, a bonding process, the same or similar to the process as shown in FIGS. 1B to 1C and/or 4A to 4B, is performed for bonding the insulating layer 141 and the insulating layer 142, bonding the second electrical connector 120 and the first electrical connector 110. A conductive bonded layer 130 could be formed.

Then, one or more processes the same or similar to the processes as shown in FIGS. 1C to 1F are performed for forming the one or more conductors 187, the second encapsulant 172, the circuit structure 188, and/or the conductive terminal 189.

With reference to FIG. 5B, production of the package structure 500 of the embodiment may be roughly completed after the above steps. FIG. 5B is also a schematic cross-sectional view of the package structure according to an embodiment of the disclosure. A package structure 500 and/or a manufacturing method thereof are similar to the package structure 100 and/or the manufacturing method thereof. Similar film layers, devices, components or areas are denoted by the same reference numerals and have similar functions, materials, or manner of formation, and the description is omitted.

Referring to FIG. 5B, a package structure 500 includes at least one (e.g., one or more) first electronic component 161, at least one (e.g., one or more) second electronic component 162, a first insulating layer 141, a second insulating layer 142, and at least one electrical connector 110, 130 and 120; and further, includes the circuit structure 588. The second electronic component 162 is disposed between circuit structure 588 and the first electronic component 161.

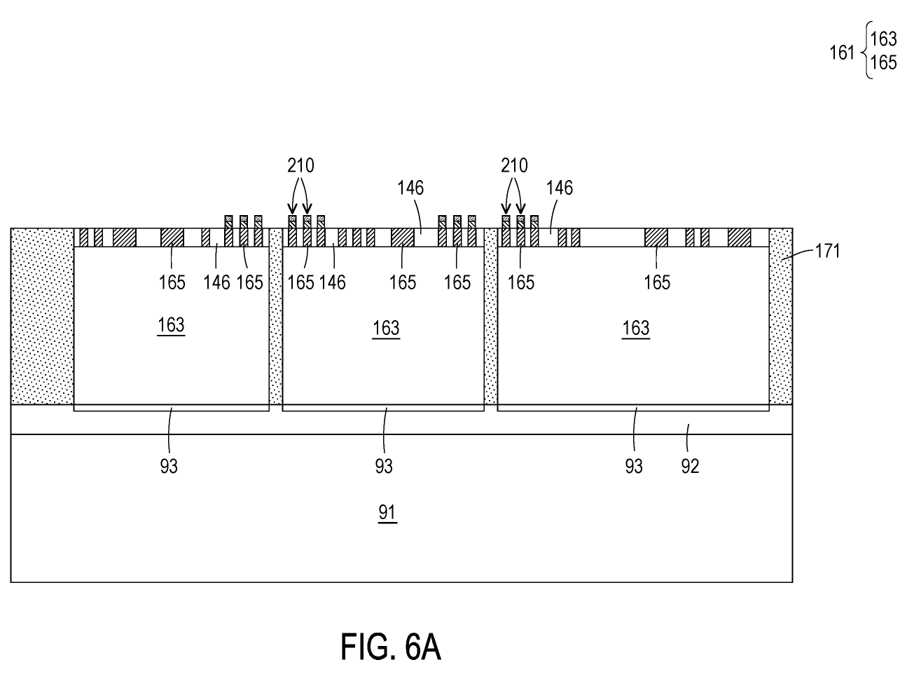

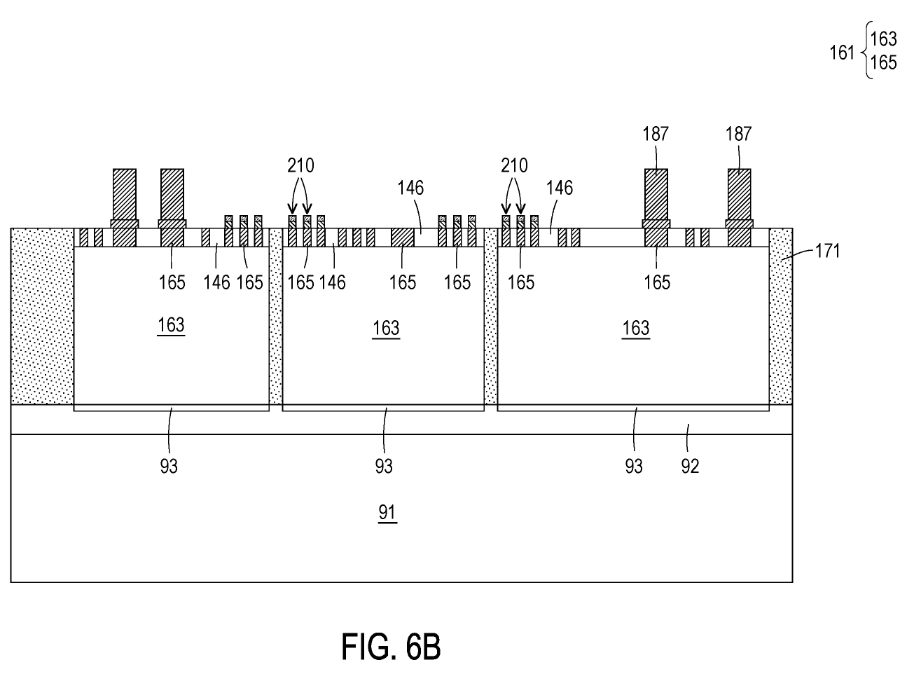

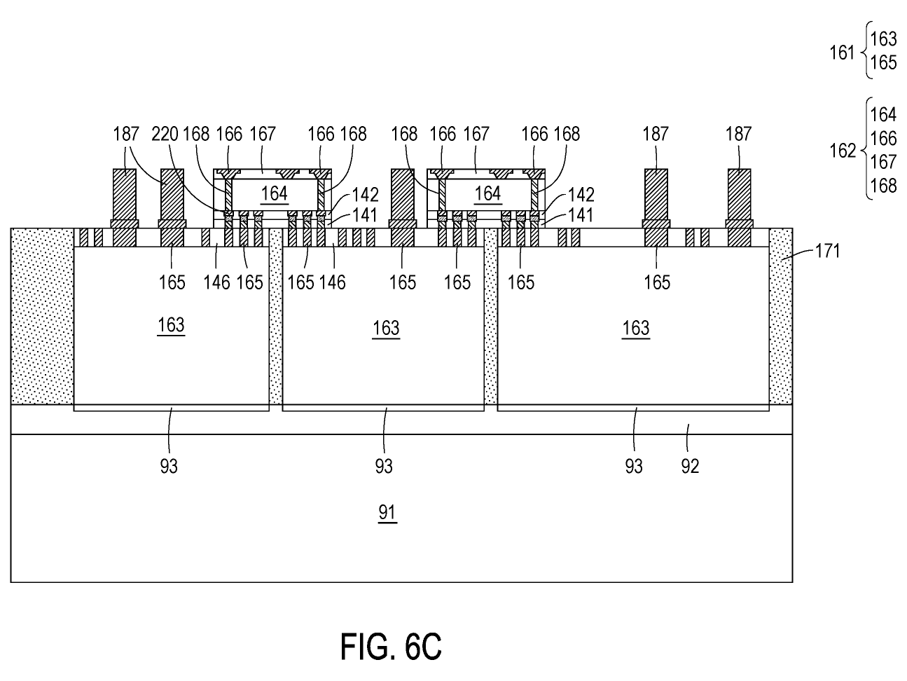

FIGS. 6A to 6B illustrate portion of cross-section views of a manufacturing method of a package structure of an embodiment of the disclosure. The structure or manufacturing method of the embodiment may be similar to the aforementioned embodiment, and similar features are denoted or labelled by the same reference numerals and have the same of similar functions, and description thereof is omitted.

Referring to FIG. 6A, a structure with a first encapsulant 171 encapsulating the first electronic components 161 is provided.

Referring to FIG. 6A continuously, one or more first electrical connectors 210 could be formed. The forming method or a structure of the first electrical connectors 210 could be similar to the aforementioned first electrical connectors 110. For example, the first electrical connector 210 may be formed by a lithography process, a sputtering process, an electroplating process, and/or a removal process, but the disclosure is not limited thereto.

Referring to FIGS. 6A to 6B, one or more conductors 187 are formed to electrically connect to one or more corresponding first electronic components 161.

In an embodiment, the conductor 187 is a pre-formed conductor. For example, before the afterward molding material is formed, a pre-formed conductor is formed by an appropriate process to electrically connect to one or more corresponding first electronic components 161.

Referring to FIGS. 6B to 6C, the second electronic component 162 could be bonded with one or more first electronic components 161. It is worth noting that in the embodiment as shown in FIGS. 6B to 6C, the one or more conductors 187 are formed; then, the second electronic component 162 could be bonded with one or more first electronic components 161. In an embodiment not shown, the second electronic component 162 could be bonded with one or more first electronic components 161; then, the one or more conductors 187 are formed.

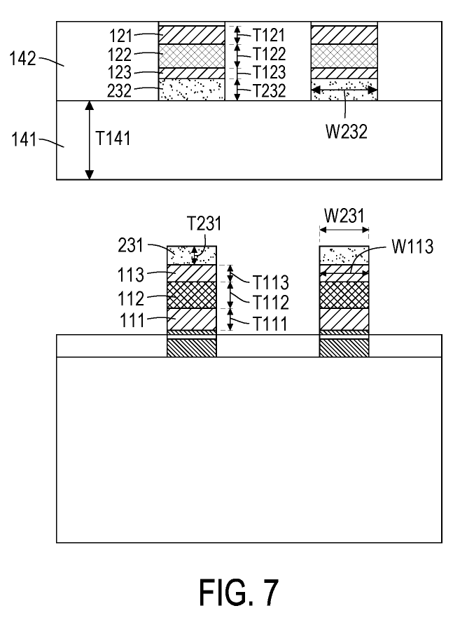

A detail of the bonding process is schematically illustrated in FIG. 7.

In an embodiment, as shown in FIG. 7 (note: the second electronic component 162 as shown in FIG. 7 is flipped upside-down), the insulating layer 141 could be disposed on the insulation layer 142, and cover the second electrical connector 220 includes a stack of a fourth conductive layer 121, a fifth conductive layer 122, a sixth conductive layer 123, and the second conductive bonding layer 232. In an embodiment, a planarization process (e.g., a CMP process) may be performed to make a surface of the second conductive bonding layer 232 (e.g., the lower surface of the second conductive bonding layer 232 as shown in FIG. 7) and a surface of the insulation layer 142 (e.g., the lower surface of the insulation layer 142 as shown in FIG. 7) substantially coplanar. In an embodiment, the second conductive bonding layer 232 is a Sn-based layer having a thickness T232 about 0.5 µm ~ 4.0 µm.

As shown in FIG. 7, the first electrical connector 210 may further include a first conductive bonding layer 231. In an embodiment, the first conductive bonding layer 231 is a Sn-based layer having a thickness T231 about 0.5 µm ~ 4.0 µm.

In an embodiment, in a top view, an outer contour of the first conductive bonding layer 231 and an outer contour of other portions of the first electrical connector 210 (e.g., the first conductive layer 111, the second conductive layer 112, and/or the third conductive layer 113) may be the same or similar. That is, a maximum horizontal dimension (e.g., the width W231) of the first conductive bonding layer 231 could be substantially the same or similar to a maximum horizontal dimension of the conductive layer underlying thereto (e.g., the width W113 of the third conductive layer 113 underlying and in contact with the first conductive bonding layer 131).

As shown in FIGS. 7 and 4B, for a subsequent bonding process, the protruded first electrical connector 210 could be configured to correspond or align with the second electrical connector 220.

In an embodiment, a height of the protruded portion of the first electrical connector 210 is substantially equal or greater than a thickness T141 of the insulating layer 141. For example, a sum of the thickness T111 of the first conductive layer 111, the thickness T112 of the second conductive layer 112, the thickness T113 of the third conductive layer 113, and the thickness T231 of the first conductive bonding layer 231 is substantially equal or greater than a thickness T141 of the insulating layer 141.

In an embodiment, a maximum horizontal dimension (e.g., the width W232) of the second conductive bonding layer 232 could be greater than a maximum horizontal dimension (e.g., the width W231) of the first conductive bonding layer 231.

As shown in FIGS. 4A to 4B, the insulating layer 141 disposed on the second electronic component 162 is bonded with the insulating layer 146 disposed on the first electronic component 161; and, the second electrical connector 220 disposed on the second electronic component 162 is bonded with the first electrical connector 210 disposed on the first electronic component 161.

Preliminarily, the second electronic component 162 and the first electronic component 161 could be configured such that the second electrical connector 220 and the first electrical connector 210 thereof face and align to each other.

Then, the protrusions (e.g., the first electrical connector 210) is inserted into the insulating layer 141; further, the first conductive bonding layer 231 and the second conductive bonding layer 232 are in contact with each other.

Before and/or during the first conductive bonding layer 231 and the second conductive bonding layer 232 being closer, and/or when the first conductive bonding layer 231 and the second conductive bonding layer 232 being in contact with, a thermal treatment is performed. Subsequently, the first electronic component 161 and the second electronic component 162 being closer continuously and/or the thermal treatment is performed continuously, so that the insulating layer 142 and the insulating layer 146 are bonded with each other, and/or the first conductive bonding layer 231 is jointed with the second conductive bonding layer 232. The thermal treatment and/or an additional treatment may be further performed, such that the first conductive bonding layer 231 and/or the second conductive bonding layer 232 may reflow, and a conductive bonded layer 130 (e.g., as shown in FIG. 4B) constituted from the first conductive bonding layer 231 (e.g., as shown in FIG. 7) and the second conductive bonding layer 232 (e.g., as shown in FIG. 7) is formed after completing the aforementioned bonding process.

Then, one or more processes the same or similar to the processes as shown in FIGS. 1D to 1F could be performed, to form a package structure substantially the same or similar to the package structure 100 as shown in FIG. 1F.

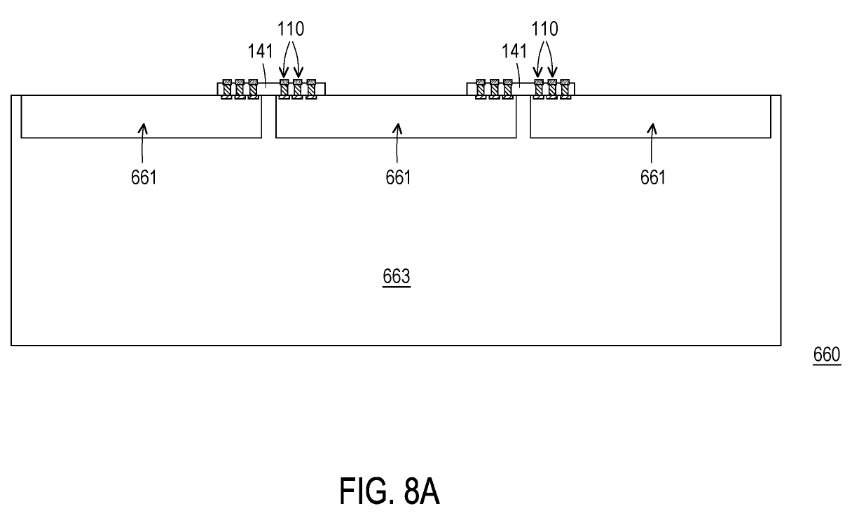

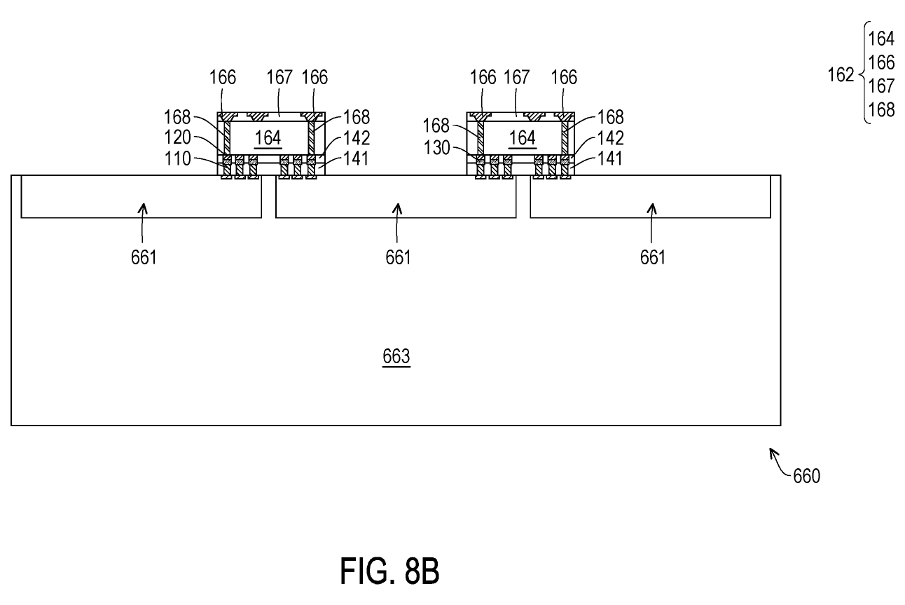

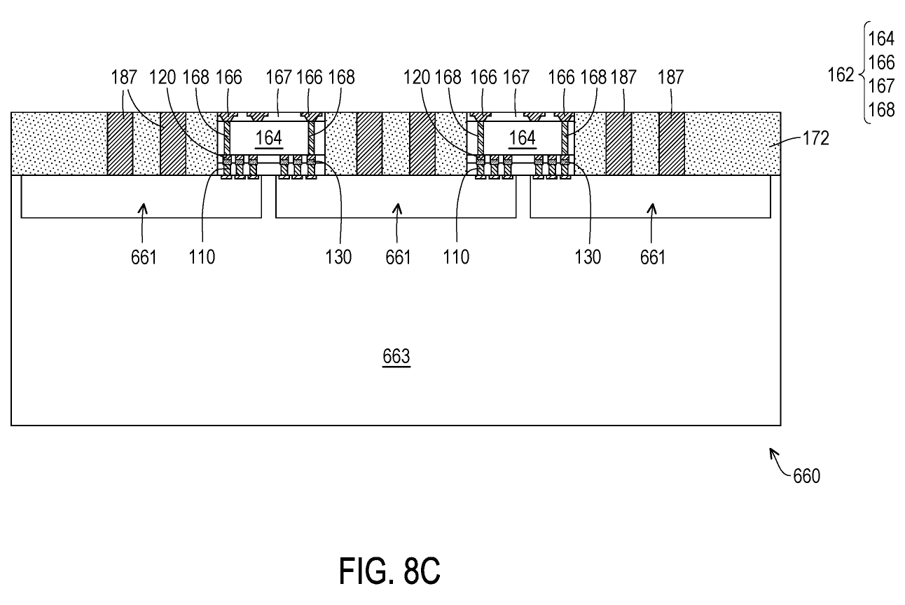

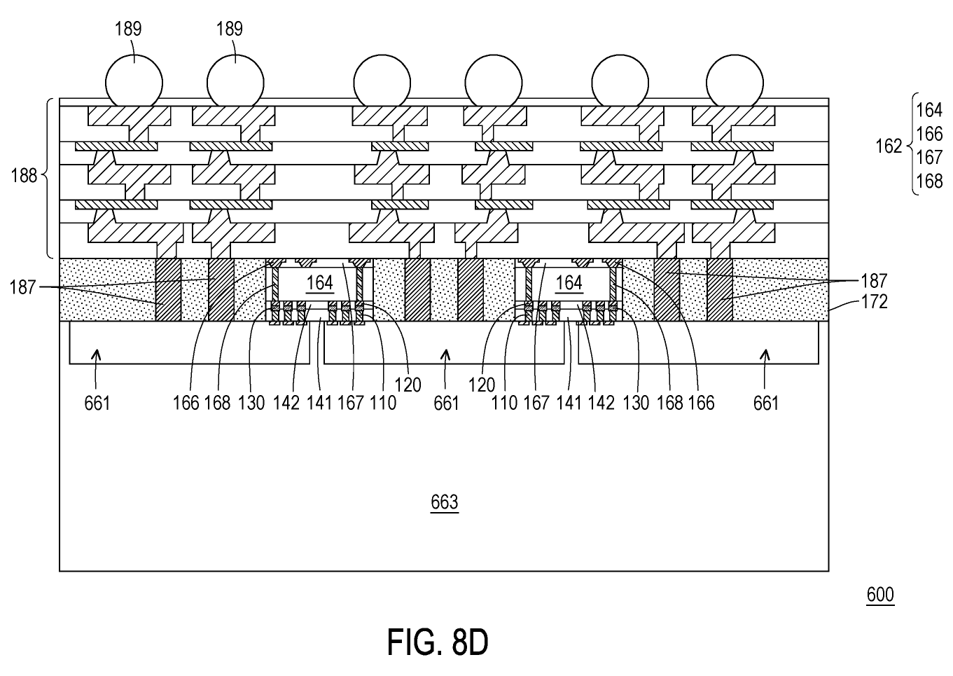

FIGS. 8A to 8D illustrate a portion of cross-section views of a manufacturing method of a package structure of an embodiment of the disclosure.

Referring to FIG. 8A, a first electronic component 660 is provided. The first electronic component 660 includes a substrate 663 having a plurality of chip regions 661 disposed thereon. The chip region 661 could be formed by an appropriate chip manufacturing process, for example, a front end of line (FEOL) process for forming one or more device areas, a middle end of line (MEOL) process for connecting one or more corresponding devices, and a back end of line (BEOL) process for forming one or more interconnects. In an embodiment, the chip regions 661 are separated by an appropriate separating structure (not shown), for example, a scribe line. The substrate 663 of the first electronic component 161 is a wafer (e.g., a semiconductor wafer), a glass substrate, or a laminated substrate, but the disclosure is not limited thereto. Taking an embodiment where the substrate 663 is a semiconductor wafer as an example, the first electronic component 660 could be referred as a known good die (KGD) wafer, which has basically completed the corresponding integrated circuit (IC) manufacturing process and undergone necessary testing (e.g., a chip probing (CP) test), but has not yet been diced.

Referring to FIG. 8A continuously, one or more first electrical connectors 110 embedded in the insulating layer 141 could be formed, which is the same or similar to the structure and/or step as shown in FIG. 8B.

As shown in FIGS. 8A to 8B, a bonding process, the same or similar to the process as shown in FIGS. 1B to 1C and/or 4A to 4B, is performed for bonding the insulating layer 141 and the insulating layer 142, bonding the second electrical connector 120 and the first electrical connector 110. A conductive bonded layer 130 could be formed.

As shown in FIGS. 8B to 8C, an encapsulant 172 is formed, which is the same or similar to the structure and/or step as shown in FIGS. 1C to 1D.

Referring to FIG. 8C continuously, one or more conductors 187 penetrating through the encapsulant 172 are formed to electrically connect to one or more corresponding chip regions 661.

As shown in FIGS. 8C to 8D, a circuit structure 188 and/or one or more conductive terminals 189 electrically connected to the second electronic component 162 and/or the conductor 187 is formed by an appropriate process, which is the same or similar to the structure and/or step as shown in FIGS. 1D to 1E.

In an embodiment, a plurality of package structures 600 may be formed through a singulation process by dicing the substrate along a separating structure (e.g., scribe line) formed or disposed on the substrate 663, the encapsulant 172, and the circuit structure 188. It should be noted that similar element reference numerals are applied to the singulated elements after the singulation process, and singulated elements follows the same element reference numerals rules described above, and will not be repeated or particularly illustrated here.

With reference to FIG. 8D, production of the package structure 600 of the embodiment may be roughly completed after the above steps. FIG. 8D is also a schematic cross-sectional view of the package structure according to an embodiment of the disclosure. A package structure 600 and/or a manufacturing method thereof are similar to the package structure 100 and/or the manufacturing method thereof. Similar film layers, devices, components or areas are denoted by the same reference numerals and have similar functions, materials, or manner of formation, and the description is omitted.

Referring to FIG. 8D, a package structure 600 includes at least one first electronic component 660, at least one (e.g., one or more) second electronic component 162, a first insulating layer 141, a second insulating layer 142, and at least one electrical connector 110, 130 and 120. The first electronic component 660 could include a plurality of chip regions 661 corresponding to a single substrate 663.

In an embodiment not shown, a package structure substantially the same or similar to the package structure 600could be formed by a manufacturing method including one or more processes similar to one or more processes as shown in FIGS. 6A-4C and 7.

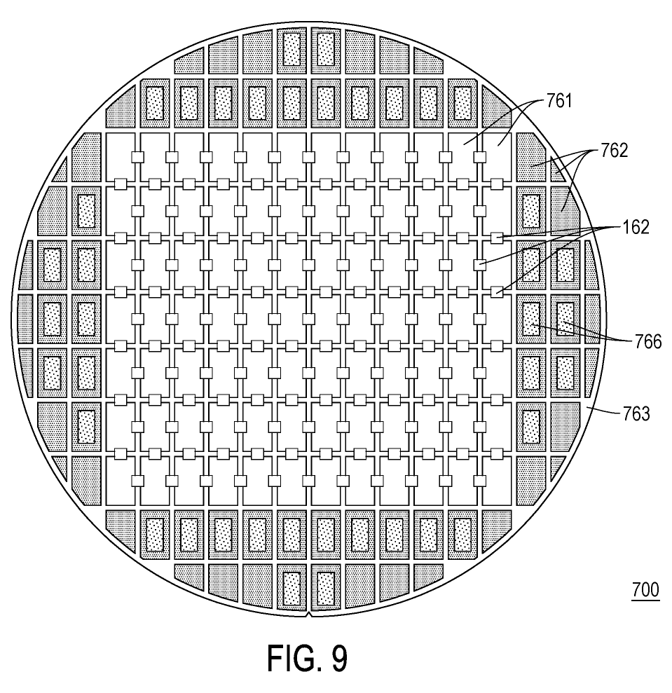

FIG. 9 illustrate a portion of top view of a manufacturing method of a package structure of an embodiment of the disclosure. In an embodiment, the structure 700 as shown in FIG. 9 could be a top view corresponding to a structure the same or similar to the structure as shown in FIG. 8B.

Referring to FIG. 9, a first electronic component 760 is provided. The first electronic component 760 includes a substrate 763 having a plurality of chip regions 761 disposed thereon. The substrate 763 could be a semiconductor wafer. A form or a formation process of the chip regions 761 could be the same or similar to the form or the formation process of the aforementioned chip regions 661. In a top view, one or more non-chip regions 762 could be disposed between the edge of the substrate 763 (may be referred as the “wafer-edge”) and the chip regions 761. In an embodiment, the non-chip regions 762 does not have a function the same or similar to the function as the chip region 761, and could be referred as an unused region or a dummy region. It is worth noting that the term “unused” or “dummy” corresponding to the non-chip regions 762 is compared to the chip regions 761. For a manufacturing process of package structure or other purposes, the non-chip regions 762 may have an appropriate function, for example, improving a process quality (e.g., reducing the warpage) or for alignment. In an embodiment, the chip regions 761 and the non-chip regions 762 are separated by an appropriate separating structure (not shown), for example, a scribe line. In addition, for clarity, not all the chip regions 761 and the non-chip regions 762 are labelled one by one in FIG. 9.

Referring to FIG. 9 continuously, a bonding process, the same or similar to the process as shown in FIGS. 1B to 1C, FIGS. 4A to 4B, FIGS. 7 and 4B, and/or FIGS. 8A to 8B, is performed for bonding. One or more second electronic components 162 are provided to be bonded with the one or more chip regions 761.

In an embodiment, one or more components 766 is disposed on the substrate 763 corresponding to at least one of the non-chip regions 762. The components 766 does not overlap the chip regions 761 substantially. In an embodiment, the component 766 could be referred as an unused chip or a dummy chip. It is worth noting that the term “unused” or “dummy” corresponding to the component 766 is compared to the second electronic components 162. For a manufacturing process of package structure or other purposes, the components 766 may have an appropriate function, for example, improving a process quality (e.g., reducing the warpage) or for alignment. In addition, for clarity, not all the components 766 and the second electronic components 162 are labelled one by one in FIG. 9.

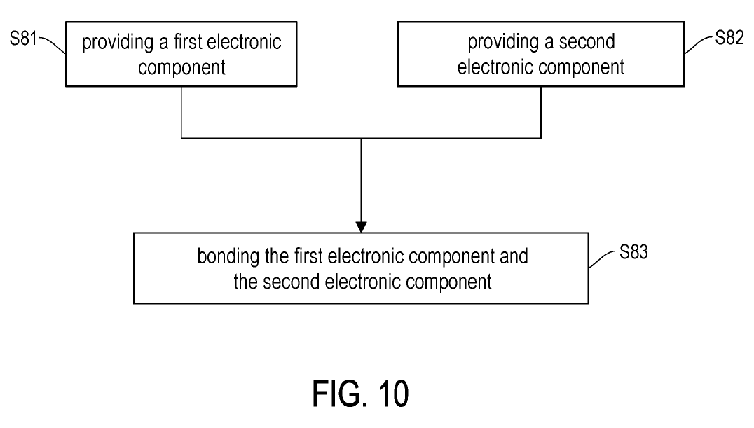

FIG. 10 illustrates a portion of flow for a manufacturing method of a package structure of an embodiment of the disclosure.

At act 81, a first electronic component is provided. FIGS. 1A, 1B, 5A, 6A, 8A and/or 9 illustrate views corresponding to various embodiments of act 81.

In an embodiment, the first electronic component is provided with a plurality thereof. In an embodiment, the first electronic component is provided with a substrate having a plurality of chip regions disposed thereon.

In an embodiment, an insulating layer (e.g., an insulating layer the same or similar to the aforementioned insulating layer 141) is disposed on the first electronic component. In an embodiment, one or more electrical connectors (e.g., electrical connectors the same or similar to the aforementioned first electrical connectors 110) embedded in the aforementioned insulating layer could be formed.

In an embodiment, an encapsulant (e.g., an encapsulant the same or similar to the aforementioned first encapsulant 171) is formed to encapsulate the one or more first electronic components.

In an embodiment, a circuit structure (e.g., a circuit structure the same or similar to the aforementioned circuit structure 588) is formed on the one or more first electronic components.

At act 82, a second electronic component is provided. FIGS. 1C, 5B, 6C, 8B and/or 9 illustrate views corresponding to various embodiments of act 82.

In an embodiment, the second electronic component is provided with a plurality thereof.

In an embodiment, an insulating layer (e.g., an insulating layer the same or similar to the aforementioned insulating layer 142) is disposed on the second electronic component. In an embodiment, one or more electrical connectors (e.g., electrical connectors the same or similar to the aforementioned second electrical connectors 120) embedded in the aforementioned insulating layer could be formed.

At act 83, bonding the first electronic component and the second electronic component. FIGS. 1C, 4A to 4B, 5B, 7 and 4B, 8B and/or 9 illustrate views corresponding bonding process to various embodiments of act 83.

In an embodiment, an encapsulant (e.g., an encapsulant the same or similar to the aforementioned second encapsulant 172) is formed to encapsulate the one or more second electronic components.

In an embodiment, a circuit structure (e.g., a circuit structure the same or similar to the aforementioned circuit structure 188) is formed on the one or more second electronic components. In an embodiment, one or more conductive terminals (e.g., conductive terminals the same or similar to the aforementioned conductive terminals 189) are formed after forming the aforementioned circuit structure.

In the aforementioned embodiments, the conductive layer may be a single layer structure or a multi-layer structure; if it is a conductive layer of a multi-layer structure, there may be no insulating material between the conductive multi-layer structure. In the aforementioned embodiments, an insulating layer may be a single layer structure or a multi-layer structure; if it is an insulating layer of a multi-layer structure, there may be no conductive material between the insulating multi-layer structure.

The drawings of the disclosure are only schematic illustrations. For example, two different and unconnected conductors (e.g., two circuits) in a cross-sectional view may be electrically connected to each other by another conductor (e.g., another circuit and/or a via, but not limited) in another cross-section view that is not shown.

In an embodiment, the aforementioned package structure is referred as a 3D packaging or a 3DIC devices. In an embodiment, the aforementioned package structure is a portion of a 3D packaging or a 3DIC devices.

In accordance with some embodiments of the present disclosure, a package structure includes a first electronic component, a second electronic component, a first insulating layer, a second insulating layer, and an electrical connector. The first insulating layer and the second insulating layer are stacked and disposed between the first electronic component and the second electronic component. The electrical connector penetrates through the first insulating layer and the second insulating layer to electrically connect the first electronic component and the second electronic component. A material of the first insulating layer is different from a material of the second insulating layer. In an embodiment, a hardness of the first insulating layer is lower than a hardness of the second insulating layer. In an embodiment, the material of the first insulating layer and the material of the second insulating layer includes polymer. In an embodiment, a glass transition point of the first insulating layer is lower than a glass transition point of the second insulating layer. In an embodiment, the electrical connector includes a first electrical connector embedded in the first insulating layer, a second electrical connector embedded in the second insulating layer, and a conductive bonded layer disposed between and physically connected to the first electrical connector and the second electrical connector, wherein a width of the second electrical connector is wider than a width of the first electrical connector. In an embodiment, a width of the conductive bonded layer is wider than the width of the second electrical connector. In an embodiment, the first insulating layer and the second insulating layer partially overlap with the first electronic component. In an embodiment, the package structure further includes an encapsulant encapsulating the second electronic component and laterally covering the first insulating layer and the second insulating layer.

In accordance with some embodiments of the present disclosure, a package structure includes a first electronic component, a second electronic component, and an electrical connector. The electrical connector is disposed between and electrically connected to the first electronic component and the second electronic component. The electrical connector includes a first electrical connector, a second electrical connector, and a conductive bonded layer. The first electrical connector is disposed corresponding to the first electronic component. The second electrical connector is disposed corresponding to the second electronic component. The conductive bonded layer is disposed between and physically connected to the first electrical connector and the second electrical connector. A width of the conductive bonded layer is wider than at least one of a width of the first electrical connector and a width of the second electrical connector. In an embodiment, the width of the second electrical connector is wider than the width of the first electrical connector; and the conductive bonded layer further covers a side wall of the first electrical connector. In an embodiment, the width of the conductive bonded layer is wider than both of the width of the first electrical connector and the width of the second electrical connector; and the conductive bonded layer further covers a side wall of the first electrical connector. In an embodiment, the conductive bonded layer further covers a side wall of the second electrical connector. In an embodiment, the width of the second electrical connector is wider than the width of the first electrical connector; and a covering depth of the conductive bonded layer coving the side wall of the first electrical connector is larger than a covering depth of the conductive bonded layer covering the side wall of the second electrical connector. In an embodiment, in a top view, a projecting range of the conductive bonded layer is larger than at least one of a projecting range of the first electrical connector and a projecting range of the second electrical connector. In an embodiment, in a top view, at least one of a projecting range of the first electrical connector and a projecting range of the second electrical connector is within a projecting range of the conductive bonded layer. In an embodiment, in the top view, both of the projecting range of the first electrical connector and the projecting range of the second electrical connector is within the projecting range of the conductive bonded layer.

In accordance with some embodiments of the present disclosure, a manufacturing method of a package structure includes: providing a first electronic component having a first electrical connector embedded in a first insulating layer; providing a second electronic component having a second electrical connector embedded in a second insulating layer; and bonding the first electronic component and the second electronic component by bonding the first electrical connector and the second electrical connector to each other and bonding the first insulating layer and the second insulating layer to each other, wherein: a material of the first insulating layer is different from a material of the second insulating layer. In an embodiment, the first electrical connector is protruded from the first insulation layer; the second electrical connector is recessed in the second insulation layer; and a hardness of the first insulating layer is lower than a hardness of the second insulating layer; or, a glass transition point of the first insulating layer is lower than a glass transition point of the second insulating layer. In an embodiment, the first electrical connector includes a conductive bonding layer protruding from the first insulation layer and a conductive layer beneath the conductive bonding layer; a melting point of the conductive bonding layer is lower a melting point of the conductive layer; and a width of the conductive bonding layer is wider than a width of the conductive layer. In an embodiment, the material of the first insulating layer and the material of the second insulating layer includes polymer.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first electronic component;
a second electronic component;
a first insulating layer;
a second insulating layer; and
an electrical connector, wherein:
the first insulating layer and the second insulating layer are stacked and disposed between the first electronic component and the second electronic component,
the electrical connector penetrates through the first insulating layer and the second insulating layer to electrically connect the first electronic component and the second electronic component; and
a material of the first insulating layer is different from a material of the second insulating layer.

2. The package structure of claim 1, wherein a hardness of the first insulating layer is lower than a hardness of the second insulating layer.

3. The package structure of claim 1, wherein the material of the first insulating layer and the material of the second insulating layer comprises polymer.

4. The package structure of claim 3, wherein a glass transition point of the first insulating layer is lower than a glass transition point of the second insulating layer.

5. The package structure of claim 1, wherein the electrical connector comprises:
a first electrical connector, embedded in the first insulating layer;
a second electrical connector, embedded in the second insulating layer; and
a conductive bonded layer, disposed between and physically connected to the first electrical connector and the second electrical connector,
wherein a width of the second electrical connector is wider than a width of the first electrical connector.

6. The package structure of claim 5, wherein a width of the conductive bonded layer is wider than the width of the second electrical connector.

7. The package structure of claim 1, wherein the first insulating layer and the second insulating layer partially overlap with the first electronic component.

8. The package structure of claim 1, further comprising:
an encapsulant, encapsulating the second electronic component and laterally covering the first insulating layer and the second insulating layer.

9. A package structure, comprising:
a first electronic component;
a second electronic component; and
an electrical connector, disposed between and electrically connected to the first electronic component and the second electronic component, wherein the electrical connector comprises:
a first electrical connector, disposed corresponding to the first electronic component;
a second electrical connector, disposed corresponding to the second electronic component; and
a conductive bonded layer, disposed between and physically connected to the first electrical connector and the second electrical connector, wherein a width of the conductive bonded layer is wider than at least one of a width of the first electrical connector and a width of the second electrical connector.

10. The package structure of claim 9, wherein:
the width of the second electrical connector is wider than the width of the first electrical connector; and
the conductive bonded layer further covers a side wall of the first electrical connector.

11. The package structure of claim 9, wherein:
the width of the conductive bonded layer is wider than both of the width of the first electrical connector and the width of the second electrical connector; and
the conductive bonded layer further covers a side wall of the first electrical connector.

12. The package structure of claim 11, wherein:
the conductive bonded layer further covers a side wall of the second electrical connector.

13. The package structure of claim 12, wherein:
the width of the second electrical connector is wider than the width of the first electrical connector; and
a covering depth of the conductive bonded layer coving the side wall of the first electrical connector is larger than a covering depth of the conductive bonded layer covering the side wall of the second electrical connector.

14. The package structure of claim 9, wherein in a top view, a projecting range of the conductive bonded layer is larger than at least one of a projecting range of the first electrical connector and a projecting range of the second electrical connector.

15. The package structure of claim 9, wherein in a top view, at least one of a projecting range of the first electrical connector and a projecting range of the second electrical connector is within a projecting range of the conductive bonded layer.

16. The package structure of claim 15, wherein in the top view, both of the projecting range of the first electrical connector and the projecting range of the second electrical connector is within the projecting range of the conductive bonded layer.

17. A manufacturing method of a package structure, comprising:
providing a first electronic component having a first electrical connector embedded in a first insulating layer;
providing a second electronic component having a second electrical connector embedded in a second insulating layer; and
bonding the first electronic component and the second electronic component by bonding the first electrical connector and the second electrical connector to each other and bonding the first insulating layer and the second insulating layer to each other, wherein:
a material of the first insulating layer is different from a material of the second insulating layer.

18. The manufacturing method of claim 17, wherein:
the first electrical connector is protruded from the first insulation layer;
the second electrical connector is recessed in the second insulation layer; and
a hardness of the first insulating layer is lower than a hardness of the second insulating layer; or, a glass transition point of the first insulating layer is lower than a glass transition point of the second insulating layer.

19. The manufacturing method of claim 17, wherein:
the first electrical connector comprises a conductive bonding layer protruding from the first insulation layer and a conductive layer beneath the conductive bonding layer;
a melting point of the conductive bonding layer is lower a melting point of the conductive layer; and
a width of the conductive bonding layer is wider than a width of the conductive layer.

20. The manufacturing method of claim 17, wherein the material of the first insulating layer and the material of the second insulating layer comprises polymer.
